(19) United States
(12) Patent Application Publication
(10) Pub. No.: US 2025/0244659 A1
(43) Pub. Date: Jul. 31, 2025

(54) METHOD FOR REMOVING DEFECT ON EUV MASK

(71) Applicant: NANYA TECHNOLOGY CORPORATION, New Taipei city (TW)

(72) Inventor: Chien-Hsien LIU, New Taipei City (TW)

(21) Appl. No.: 18/424,322

(22) Filed: Jan. 26, 2024

(51) Int. Cl. G03F 1/72; G03F 1/22; G03F 1/48; G03F 1/54; G03F 1/80

(52) U.S. Cl. CPC G03F 1/72; G03F 1/22; G03F 1/48; G03F 1/54; G03F 1/80

(57) ABSTRACT

Embodiments of this disclosure provide a method for removing a defect on a EUV mask, including the following steps. An EUV mask with at least one defect on the EUV mask is received, wherein an absorbent layer and a pattern layer collectively form a pattern with covering portions and exposing portions on the capping layer, and the at least one defect forms a covered region in the exposing portions on the capping layer. A directional etching process is performed at a first oblique angle on the at least one defect in an etching chamber to shrink the at least one defect on the EUV mask through etching particles. The directional etching process is continued to performed at a second oblique angle one defect on the at least one defect to fully remove the at least one defect, wherein the second oblique angle is greater than the first oblique angle.

### BACKGROUND

### Field of Invention

The present disclosure relates to a method for removing a defect on a EUV mask. More particularly, the present disclosure relates to a method for removing a defect on a EUV mask by etching.

### Description of Related Art

In manufacturing an integrated circuit (IC), the circuit design of a substrate of a wafer is translated into a layout. Then, the layout is transferred onto the substrate of the wafer by using photolithography. For example, a mask, such as an Extreme Ultraviolet (EUV) mask, is applied on the substrate of the wafer, and a radiation source is shone on the mask to make a pattern on the substrate of the wafer based on the layout.

However, as the requirements for ICs become more and more precise and photolithography technology becomes more and more sophisticated, fall on particle defect on the mask, such EUV mask, fallen on an important region of the EUV mask results in image problems on the substrate of the wafer. As a result, a method of moving a defect on EUV mask is much needed in the field.

### SUMMARY

Embodiments of this disclosure provide a method for removing a defect on a EUV mask, and the method includes the following steps. An EUV mask with at least one defect on the EUV mask is received, wherein the EUV mask includes a capping layer, an absorbent layer on the capping layer and a pattern layer on the absorbent layer, the absorbent layer and the pattern layer collectively form a pattern with a plurality of covering portions and a plurality of exposing portions on the capping layer, and the at least one defect forms a covered region in the plurality of exposing portions on the capping layer. A directional etching process is performed at a first oblique angle with respect to a normal direction of a surface of the at least one defect on the at least one defect in an etching chamber to shrink the at least one defect on the EUV mask through a plurality of etching particles, wherein the covered region formed by the at least one defect is also shrunk due to after performing the directional etching process. The directional etching process is continued to performed at a second oblique angle with respect to the normal direction of the at least one defect on the at least one defect to fully remove the at least one defect, wherein the second oblique angle is greater than the first oblique angle.

In some embodiments, each of the first oblique angle and the second oblique angle is greater than 30 degree.

In some embodiments, each of the first oblique angle and the second oblique angle is greater than 30 degree and less than 90 degree.

In some embodiments, the first oblique angle is gradually increased to the second oblique angle depending on a size and a position of the at least one defect.

In some embodiments, a type of the at least one defect includes Sn, Al, Mo, Ni, Ta or combinations thereof.

In some embodiments, the directional etching process is controlled by adjusting etching conditions including a type of the etching particles, a concentration of the etching particles, a flow rate of the etching particles, a reaction pressure applied to the EUV mask, a radio frequency applied to the EUV mask, a bias power applied to the EUV mask, a temperature applied to the EUV mask or combinations thereof.

In some embodiments, the directional etching process is performed by using gas.

In some embodiments, the at least one defect has an etching rate greater than etching rates of the pattern layer, absorbent layer and the capping layer.

In some embodiments, based on the type of the defect, one or more the etching conditions is controlled to make an etching rate of the at least one defect greater than the etching rates to the pattern layer, absorbent layer and the capping layer.

In some embodiments, the directional etching process comprises a reactive-ion etching process, a plasma etching process and a sputter etching process.

Embodiments of this disclosure provide a method for removing a defect on a EUV mask, and the method includes the following steps. An EUV mask with at least one defect on the EUV mask is received, wherein the EUV mask includes a capping layer, an absorbent layer on the capping layer and a pattern layer on the absorbent layer. The EUV mask with the at least one defect is put on a wafer chuck in an etching chamber. A plurality of etching particles are guided into the etching chamber. The at least one defect is etched through the plurality of etching particles at an oblique angle with respect to a normal direction of the at least one defect until the at least one defect vanished, wherein the oblique angle is varied as the at least one defect shrinks until vanished, and the oblique angle is non-horizontal relative to a top surface of the capping layer. Etching products produced during etching the at least one defect are purged.

In some embodiments, the oblique angle is greater than 30 degree.

In some embodiments, the oblique angle is associated with a size and a position of the at least one defect.

In some embodiments, the oblique angle incident on the at least one defect gradually becomes lager as the at least one defect shrunk.

In some embodiments, a first etching rate of the at least one defect is greater than a second etching rate of the capping layer, the first etching rate of the at least one defect is greater than a third etching rate of the absorbent layer, and first etching rate of the at least one defect is greater than a fourth etching rate of the pattern layer.

In some embodiments, etching the at least one defect is performed through a directional etching process by gas.

In some embodiments, etching the at least one defect is controlled by adjusting etching conditions including a type of the plurality of etching particles, a concentration of the plurality of etching particles, a flow rate of the gas, a reaction pressure applied to the EUV mask, a radio frequency applied to the EUV mask, a bias power applied to the EUV mask, a temperature applied to the EUV mask or combinations thereof.

In some embodiments, a type of the at least one defect comprises Sn, Al, Mo, Ni, Ta or combinations thereof.

In some embodiments, based on the type of the defect, one or more the etching conditions is controlled to make the first etching rate of the defect much greater than the second etching rate of the capping layer, the third etching rate of the absorbent layer and the fourth etching rate of the pattern layer.

In some embodiments, the etching condition is adjusted depending on an appearance, the type and a strength of the at least one defect.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. The disclosure can be more fully understood by reading the following detailed description of the embodiment, with reference made to the accompanying drawings as follows.

FIGS. 1-5 are views of a method for removing a defect on an EUV mask according some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The words “comprise”, “include”, “have”, “contain” and the like used in the present disclosure are open terms, meaning including but not limited to.

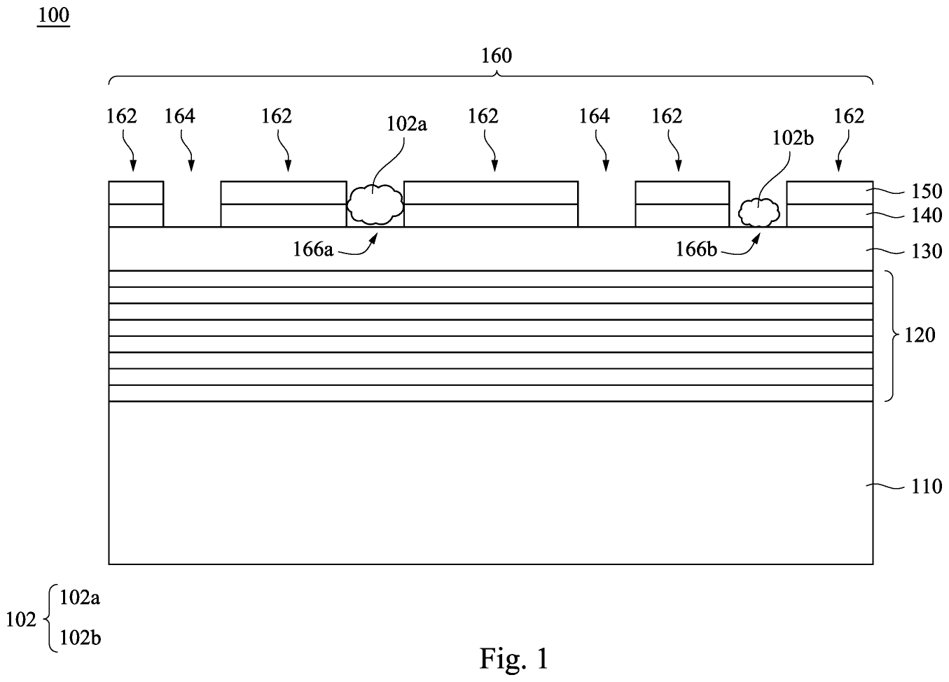

It should be noted that when the following figures, such as FIGS. 1 to 5, are illustrated and described as a series of operations or steps, the description order of these operations or steps should not be limited. For example, some operations or steps may be undertaken in a different order than in the present disclosure, or some operations or steps may occur currently, or some operations may not be used, and/or some operations or steps may be repeated. Moreover, the actual operations or steps of process stages may require additional operations or steps before, during or after removing a defect. Therefore, the present disclosure may briefly illustrate some of these additional operations or steps. Further, unless otherwise stated, the same explanations discussed for the following figures, such as FIGS. 1 to 5, apply directly to the other figures.

A defect is generated during a manufacturing process of a semiconductor wafer and falls on an EUV mask containing a pattern. Also, due to the imaging principle of the EUV mask, the defect falling in the pattern has greater impact on a lithography process of the semiconductor wafer, such as defect on a capping layer of the EUV mask and between the patterns in an absorbent layer of the EUV mask and a pattern layer of the EUV mask. Therefore, embodiments of this disclosure is provided for removing the defect on the EUV mask a validation tool stage of manufacturing the semiconductor wafer. Please refer to the following descriptions with FIGS. 1 to 5 to understand a method for removing a defect on an EUV mask provided by the embodiments of this disclosure.

Please refer to FIG. 1. An EUV mask 100 with at least one defect 102a/102b on the EUV mask 100 is received, and the defects 102a and 102b may be collectively called the defect 102. The EUV mask 100 includes a substrate 110, such as a low thermal expansion material (LTEM) substrate, a multi-reflective layer 120 on the substrate 110, a capping layer 130 on the multi-reflective layer 120, an absorbent layer 140 on the capping layer 130 and a pattern layer 150 on the absorbent layer 140. The multi-reflective layer 120 includes a plurality of Mo layers and a plurality of Si layers alternating with the Mo layers. The capping layer 130 is a Ru-based capping layer. The absorbent layer 140 is a Ta-based absorbent layer, for example, the absorbent layer 140 includes TaN. It is worth to mention that the defect 102a/102b illustrated in FIG. 1 is two, but the number of the defects 102a/102b is not limited thereto. As well, an appearance of each of the defects 102a/102b illustrated in FIG. 1 is close to an oval shape, but each of the defects 102a/102b may be also round or irregular and a surface of each of the defects 102a/102b may be uneven, and this disclosure is not limited thereto.

As shown in FIG. 1, the absorbent layer 140 and the pattern layer 150 collectively form a pattern 160 for manufacturing the semiconductor wafer. The pattern 160 contains a plurality of covering portions 162 and a plurality of exposing portions 164 on the capping layer 130. The defect 102a forms a covered region 166a in the exposing portions 164 on a top surface of the capping layer 130, and the defect 102b forms a covered region 166b in the exposing portions 164 on the top surface of the capping layer 130. Also, since a size of the defect 102a and the defect 102b is different, the defect 102a fully covers the top surface of the capping layer 130 between the covering portions 162 while the defect 102b partially covers the top surface of the capping layer 130 between the covering portions 162. No matter the defect 102a or the defect 102b imaging onto the semiconductor wafer along with the pattern 160 results in imaging problems.

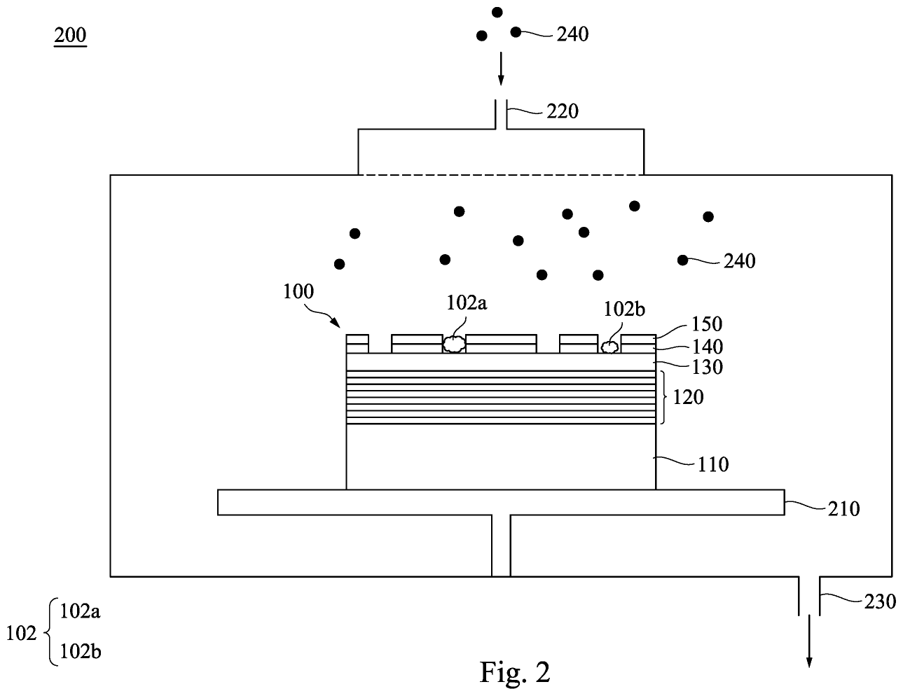

Next, please refer to FIG. 2. The EUV mask 100 with the defects 102a and 102b is put in an etching chamber 200 for performing a directional etching process to remove the defects 102a and 102b on the EUV mask 100. In some embodiments, the directional etching process is performed by a dry etching through gas. Moreover, the gas includes a plurality of etching particles 240, and the etching particles 240 are served as an etchant. In some embodiments, the gas includes halogen-based gas, such as Cl⁻-based gas, F⁻-based gas or combinations thereof. In addition, the etching chamber 200 includes a wafer chuck 210 for holding the EUV mask 100, an inlet hole 220 for receiving a plurality of etching particles 240 and an outlet hole 230 for purging gases. When performing the directional etching process, the etching particles 240 are input into the etching chamber 200 for etching the defect 102a/102b to shrink the defect 102a/102b until vanished, controlled by adjusting etching conditions. In some embodiments, the etching conditions include a type of the etching particles 240, a concentration of the etching particles 240, a flow rate of the gas input into the etching chamber 200, a reaction pressure applied to the EUV mask 100, a radio frequency (RF) applied to the EUV mask 100, a bias power applied to the EUV mask 100, a temperature applied to the EUV mask 100 or combinations thereof. In some embodiments, a type of each of the defect 102a/102b includes Sn, Al, Mo, Ni, Ta or combinations thereof. Moreover, depending on characteristics of the defect, such as a strength of the defect (soft or hard), etching resistance and/or thermal sensitivity of the defect, one or more etching conditions may be adjusted.

In some embodiments, the directional etching process includes a reactive-ion etching (RIE) process, a plasma etching process, a sputter etching process or combinations thereof. In some embodiments, the etching particles 240 include charged ions, free radicals, electrons or combinations thereof.

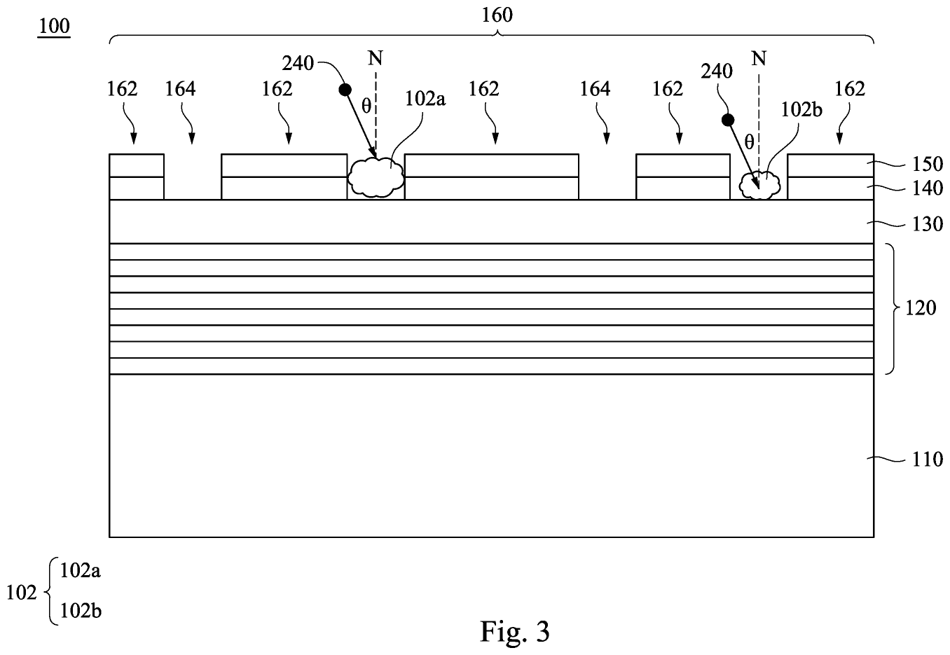

Further, please refer to FIGS. 3 to 5. The directional etching process is performed to remove the defect on the EUV mask 100 by using the etching particles 240. The etching particles 240 are guided to the defect 102a/102b at an oblique angle θ with respect to a normal direction N of a surface of the defect 102a/102b. For example, an arrow drawn in FIG. 3 is referred to as a direction in which the etching particles 240 are incident on the defect 102a/102b to shrink the defect 102a/102b until the defect 102a/102b vanished. It is worth to mention that for simplicity of figures, the etching particle 240 incident on the defect 102a/102b is one, but in practice, multiple etching particles 240 may be incident on the defect 102a/102b at the oblique angle θ at the same time.

Furthermore, in FIG. 3, the defect 102a/102b is etched through the oblique angle θ with respect to the normal direction N, wherein the oblique angle θ is non-horizontal relative to the top surface of the capping layer 130. Further, the oblique angle θ is changed based on the size of the defect 102a/102b because the oblique angle θ is related to the normal direction N of the surface of the defect 102a/102b. For example, the size of the defect 102a is greater than the size of the defect 102b, the oblique angle θ incident to the defect 102a and the oblique angle θ incident to the defect 102b may be equivalent or different. In some embodiments, the oblique angle θ is changed depending on a position of the defect on the EUV mask 100. For example, the defect 102a is located on the top surface of the capping layer 130 between the covering portions 162 and contacts side walls of the absorbent layer 140 and side walls of the pattern layer 150, while the defect 102b is located on the capping layer 130 but does not contact the side wall of the absorbent layer 140 and the side wall of the pattern layer 150. Thus, the position of the defect 102a relative to the surface of the capping layer 130 is different from the position of the defect 102b relative to the surface of the capping layer 130, the oblique angle θ incident to the defect 102a and the oblique angle θ incident to the defect 102b may be equivalent or different. In some embodiments, the oblique angle θ is greater than 30 degree. In some embodiments, the oblique angle θ is greater than 30 degree and less than 90 degree.

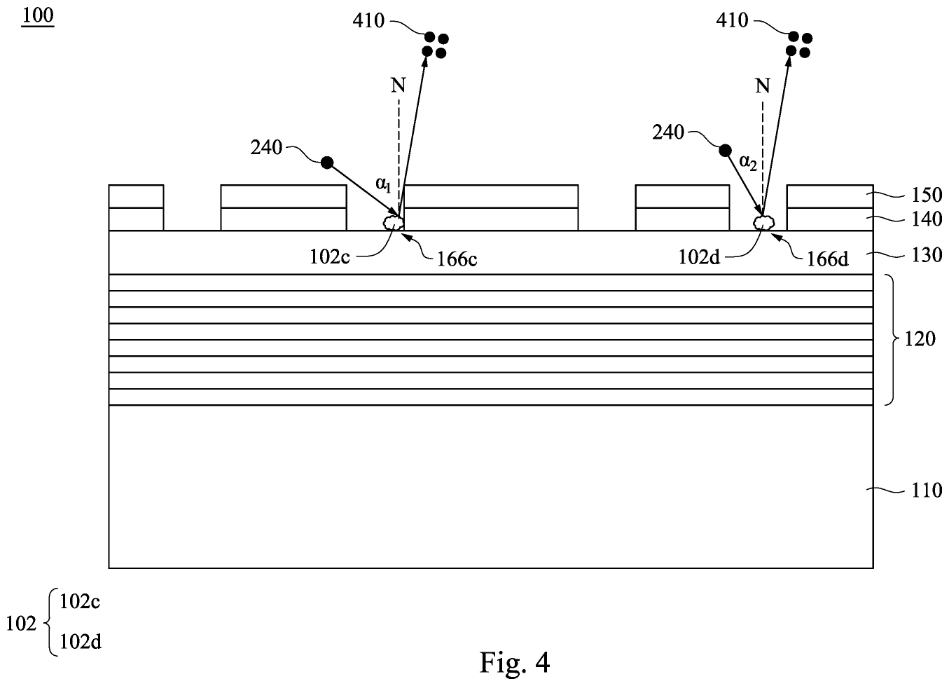

Further, as shown in FIG. 4, as the defect 102c shrunk, the defect 102a is etched through the oblique angle θ (e.g. in FIG. 3) varied to the oblique angle α1 with respect to the normal direction N of the surface of the defect 102c. In some embodiments, the oblique angle θ with respect to the normal direction N is increased to the oblique angle α1 with respect to the normal direction N depending on the size of the defect 102. In some embodiments, the oblique angle θ is gradually increased to the oblique angle α1 depending on the size of the defect 102. In this illustrative embodiment of the oblique angle α1, due to the oblique angle θ of defect 102a (e.g. in FIG. 3), the etching particles 240 make the defects 102a (e.g. in FIG. 3) shrink into the defect 102c and be located in a space between the top surface of the capping layer 130 and the side surface of the absorbent layer 140. That is, the covered region 166a formed by the defect 102a (e.g. in FIG. 3) becomes reduced into a covered region 166c formed by the defect 102c. Also, due to the size and the position of the defect 102c, the oblique angle α1 is greater than the oblique angle θ.

In some embodiments, as the defect 102d shrunk, the defect 102b (e.g. in FIG. 3) is etched through the oblique angle θ (e.g. in FIG. 3) varied to the oblique angle α2 with respect to the normal direction N of the surface of the defect 102d. In this illustrative embodiment of the oblique angle α2, due to the position of the defect 102b (e.g. in FIG. 3) and the oblique angle θ (e.g. in FIG. 3), the etching particles 240 make the defect 102b (e.g. in FIG. 3) shrink into the defect 102d and be located on the capping layer 130 but not contacting the side wall of the absorbent layer 140 and the side wall of the pattern layer 150. In some embodiments, the oblique angle θ with respect to the normal direction N is increased to the oblique angle α2 with respect to the normal direction N depending on the size of the defect 102. In some embodiments, the oblique angle θ with respect to the normal direction N is gradually increased to the oblique angle α2 with respect to the normal direction N depending on the size of the defect 102. Moreover, the covered region 166b formed by the defect 102b (e.g. in FIG. 3) becomes reduced into a covered region 166d formed by the defect 102d. In this way, due to the size and the position of the defect 102d, the oblique angle α2 is greater than the oblique angle θ. As well, in this illustrative embodiment, the oblique angle α2 is less than the oblique angle α1 due to the positions of the defect 102c and the defect 102d. In some embodiments, each of the oblique angles α1 and α2 is greater than 30 degree. In some embodiments, each of the oblique angles α1 and α2 is greater than 30 degree and less than 90 degree. As well, the defects 102c and 102d may be collectively called the defect 102.

In addition, in order to not make damage on the capping layer 130, the absorbent layer 140 and the pattern layer 150 during etching, based on the type of the defect 102, an etching rate of the defect 102 is modulated to be much greater than etching rates of the capping layer 130, the absorbent layer 140 and the pattern layer 150 through controlling one or more etching conditions. That is, a first etching rate of the defect 102 is greater than a second etching rate of the capping layer 130, the first etching rate of the defect 102 is greater than a third etching rate of the absorbent layer 140, and the first etching rate of the defect 102 is greater than a fourth etching rate of the pattern layer 150. Furthermore, etching products 410 are produced during the directional etching process. It is worth to mention, the number of the etching products 410 produced from the defect 102 is four, but the number of the etching products 410 is not limited thereto.

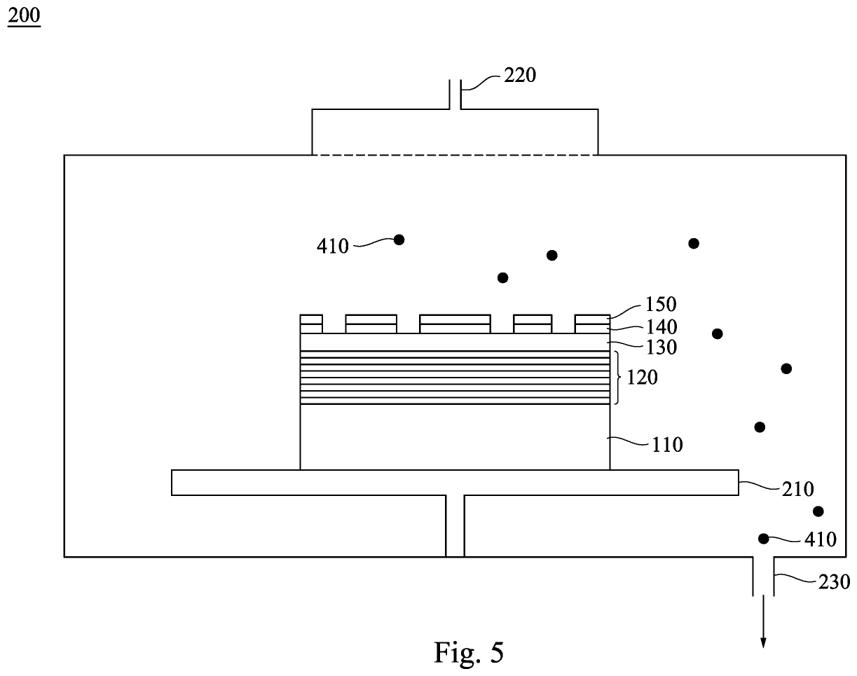

As shown in FIG. 5, the defect (e.g. the defect 102 in FIG. 3) is completely removed by the directional etching process. Also, the capping layer 130, the absorbent layer 140 and the pattern layer 150 are not damaged during the directional etching process through controlling the oblique angle (e.g. the oblique angle θ in FIG. 3) and the etching conditions depending on the different etching rates among the defect (e.g. the defect 102 in FIG. 3), the capping layer 130, the absorbent layer 140 and the pattern layer 150. In addition, after or during the directional etching process, the etching products 410 produced during the directional etching process are purged from the outlet hole 230 of the etching chamber 200 to renew an ambient environment of the etching chamber 200. Therefore, a defect-free EUV mask 100 is obtained to further produce the semiconductor wafer with the pattern 160 in the EUV mask 100.

As stated as above, the embodiments of this disclosure provides a method for removing a defect on an EUV mask. The method provided by the embodiments of this disclosure can utilize the directional etching process to move the defect on the EUV mask through adjusting the etching conditions depending on the different appearances, types and strength (e.g., soft or hard) of the defect. In addition, the etching particles are incident on the defect at the oblique angle with respect to the normal direction of the defect to accurately remove the defect on the EUV mask. Further, through adjusting the etching conditions, the etching rate of the defect is much greater than the etching rates of the capping layer, the absorbent layer and the pattern layer, achieving the advantages of quickly repairing the EUV mask without damaging the capping layer, the absorbent layer and the pattern layer of the EUV mask.

In addition, through the directional etching process, the method provided by the embodiments of this disclosure does not require to use water-based cleaning method to repair the EUV mask, saving production time and production cost.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method for removing a defect on a EUV mask, comprising:
receiving an EUV mask with at least one defect on the EUV mask, wherein the EUV mask comprises a capping layer, an absorbent layer on the capping layer and a pattern layer on the absorbent layer, the absorbent layer and the pattern layer collectively form a pattern with a plurality of covering portions and a plurality of exposing portions on the capping layer, and the at least one defect forms a covered region in the plurality of exposing portions on the capping layer;
performing a directional etching process at a first oblique angle with respect to a normal direction of a surface of the at least one defect on the at least one defect in an etching chamber to shrink the at least one defect on the EUV mask through a plurality of etching particles, wherein the covered region formed by the at least one defect is also shrunk due to after performing the directional etching process; and
continuing to perform the directional etching process at a second oblique angle with respect to the normal direction of the at least one defect on the at least one defect to fully remove the at least one defect, wherein the second oblique angle is greater than the first oblique angle.

2. The method of claim 1, wherein each of the first oblique angle and the second oblique angle is greater than 30 degree.

3. The method of claim 1, wherein each of the first oblique angle and the second oblique angle is greater than 30 degree and less than 90 degree.

4. The method of claim 1, wherein the first oblique angle is gradually increased to the second oblique angle depending on a size and a position of the at least one defect.

5. The method of claim 1, wherein a type of the at least one defect comprises Sn, Al, Mo, Ni, Ta or combinations thereof.

6. The method of claim 5, wherein the directional etching process is controlled by adjusting etching a plurality of conditions including a type of the plurality of etching particles, a concentration of the plurality of etching particles, a flow rate of the plurality of etching particles, a reaction pressure applied to the EUV mask, a radio frequency applied to the EUV mask, a bias power applied to the EUV mask, a temperature applied to the EUV mask or combinations thereof.

7. The method of claim 1, wherein the directional etching process is performed by using gas.

8. The method of claim 6, wherein the at least one defect has an etching rate greater than etching rates of the pattern layer, absorbent layer and the capping layer.

9. The method of claim 8, wherein based on the type of the defect, one or more the plurality of etching conditions is controlled to make an etching rate of the at least one defect greater than the etching rates to the pattern layer, absorbent layer and the capping layer.

10. The method of claim 1, wherein the directional etching process comprises a reactive-ion etching process, a plasma etching process and a sputter etching process.

11. A method for removing a defect on a EUV mask, comprising:
receiving an EUV mask with at least one defect on the EUV mask, wherein the EUV mask comprises a capping layer, an absorbent layer on the capping layer and a pattern layer on the absorbent layer;
putting the EUV mask with the at least one defect on a wafer chuck in an etching chamber;
guiding a plurality of etching particles into the etching chamber;
etching the at least one defect through the plurality of etching particles at an oblique angle with respect to a normal direction of a surface of the at least one defect until the at least one defect vanished, wherein the oblique angle is varied as the at least one defect shrinks until vanished, and the oblique angle is non-horizontal relative to a top surface of the capping layer; and
purging etching products produced during etching the at least one defect.

12. The method of claim 11, wherein the oblique angle is greater than 30 degree.

13. The method of claim 11, wherein the oblique angle is associated with a size and a position of the at least one defect.

14. The method of claim 13, wherein the oblique angle incident on the at least one defect gradually becomes lager as the at least one defect shrunk.

15. The method of claim 11, wherein a first etching rate of the at least one defect is greater than a second etching rate of the capping layer, the first etching rate of the at least one defect is greater than a third etching rate of the absorbent layer, and first etching rate of the at least one defect is greater than a fourth etching rate of the pattern layer.

16. The method of claim 15, wherein etching the at least one defect is performed through a directional etching process by gas.

17. The method of claim 16, wherein etching the at least one defect is controlled by adjusting a plurality of etching conditions comprising a type of the plurality of etching particles, a concentration of the plurality of etching particles, a flow rate of the gas, a reaction pressure applied to the EUV mask, a radio frequency applied to the EUV mask, a bias power applied to the EUV mask, a temperature applied to the EUV mask or combinations thereof.

18. The method of claim 17, wherein a type of the at least one defect comprises Sn, Al, Mo, Ni, Ta or combinations thereof.

19. The method of claim 18, wherein based on the type of the defect, one or more of the plurality of etching conditions is controlled to make the first etching rate of the defect much greater than the second etching rate of the capping layer, the third etching rate of the absorbent layer and the fourth etching rate of the pattern layer.

20. The method of claim 17, wherein the plurality of etching condition is adjusted depending on an appearance, the type and a strength of the at least one defect.
